(19) United States
(12) Patent Application Publication
(10) Pub. No.: US 2025/0208585 A1
(43) Pub. Date: Jun. 26, 2025

(54) WATCH MAGNETIC DETECTOR

(71) Applicant: ETA SA MANUFACTURE HORLOGÉR SUISSE, Grenchen (CH)

(72) Inventors: Dominique DUBUGNON, Saint-Prex (CH); Pierpasquale Tortora, Neuchåtel (CH); Sylvain Huot-Marchand, Eschert (CH); Raphaël Courvoisier, Corcelles (CH)

(73) Assignee: ETA SA MANUFACTURE HORLOGÉR SUISSE, Grenchen (CH)

(21) Appl. No.: 18/918,580

(22) Filed: Oct. 17, 2024

(30) Foreign Application Priority Data
Dec. 22, 2023 (EP) 23220050.1

(51) Int. Cl. G04G 21/02; G01R 33/00; G01R 33/07; G01R 33/09; G04C 10/02

(52) U.S. Cl. CPC G04G 21/02; G01R 33/0058; G01R 33/072; G01R 33/091; G04C 10/02

(57) ABSTRACT

A dial (2a, 2b) of a watch (1) including a standalone device for determining a magnetic event (3), such a dial (2a, 2b) includes a visible face (20a) and a hidden face (20b), said dial (2a, 2b) being formed by a stack (9a, 9b) of thin layers (10, 11, 12, 13, 14) of material extending between these two faces (20a, 20b), each of said layers (10, 11, 12, 13, 14) having one or more of the functional elements included in said device (3) including: at least one magnetic sensor (23), a magnetic event reporting module (4), a standalone electric power supply unit (21), and a 10 control unit (7) for managing the operation of said reporting module (4) and said at least one magnetic sensor (23).

### CROSS REFERENCE TO RELATED APPLICATIONS

This application claims priority to European Patent Application No. 23220050.1, filed on Dec. 22, 2023, the disclosures of which are incorporated by reference herein their entireties

### TECHNICAL FIELD OF THE INVENTION

The present invention relates to a watch comprising a dial including a completely standalone device for determining a magnetic event.

### TECHNICAL BACKGROUND

In the prior art, electromechanical watches with hands are known wherein the hour hand and the minute hand displaying the current time are driven by the trains of a horological movement mechanism. In this context, it might happen that, because of the presence of magnetic fields in the watch's environment, the operation of the mechanism is disturbed. As a result, although the watch's internal clock provides an accurate indication of the current time, the hour and minute hands provide a distorted indication of this current time under the effect of the external disturbance applied to the watch. It might therefore be necessary to resynchronise the position of the hour and minute hands.

In this context, it should be understood that there is a need to find a solution that does not have the drawbacks of the prior art.

### SUMMARY OF THE INVENTION

The invention aims to overcome these drawbacks by providing a watch provided with a dial including a device for determining a magnetic event which is standalone and has an effectiveness which remains constant over time.

One aspect of the invention relates to a watch dial comprising a standalone device for determining a magnetic event, such a dial comprises a visible face and a hidden face, said dial being formed by a stack of thin layers of material extending between these two faces, each of said layers comprising one or more of the functional elements comprised in said device:
at least one magnetic sensor,
a magnetic event reporting module,
a standalone electric power supply unit, and
a control unit for managing the operation of said reporting module and said at least one magnetic sensor.

In other embodiments:
said at least one magnetic sensor comprises a REED magnetic sensor, a Hall-effect sensor and/or a magnetoresistance sensor;
the module for reporting the magnetic event comprises at least one element capable of generating a light signal;
the module for reporting the magnetic event comprises at least one element capable of generating a vibratory signal;
the module for reporting the magnetic event comprises at least one element capable of generating an audible signal;
the stack of thin layers of material comprises a first layer provided with the visible face of the dial and comprising said at least one magnetic sensor and said reporting module;
said at least one magnetic sensor is arranged in a cavity formed in the hidden face of this dial;
said first layer is configured to be crossed in whole or in part by light radiation, in particular solar radiation;
said first layer is wholly or partly transparent or translucent;
the stack of thin layers of material includes a second layer comprising a photovoltaic module making up the standalone electric power supply unit;
the second layer comprises a substrate on which the photovoltaic module is printed;
said photovoltaic module is arranged on an active area of said second layer, said area being configured to receive light radiations originating from the first layer of the stack of thin layers of material;
the stack includes a third layer comprising an electrical energy accumulator making up the standalone electric power supply unit;
the third layer comprises a substrate on which the electrical energy accumulator is printed;
the stack includes a fourth layer forming a hidden face of the dial comprising the control unit;
the stack includes a third layer comprising a hidden face of the dial including the control unit and an electrical energy accumulator making up the standalone electric power supply unit;
the first layer is rigid compared to the other layers comprised in the stack of thin layers of material, which are soft;
said visible and hidden faces are flat or domed.

Another aspect of the invention relates to a watch comprising such a dial.

Advantageously, the watch comprises a mechanical, electronic or electromechanical horological movement.

### BRIEF DESCRIPTION OF THE FIGURES

The aims, advantages and features of the watch according to the invention will become clearer in the following description on the basis of at least one non-limiting embodiment illustrated by the drawings wherein:

FIG. 1 shows a perspective view of a watch comprising a dial provided with a device for determining a magnetic event which is included in a standalone manner in the watch, according to embodiments of the invention;

FIG. 2 shows an exploded view of a first variant of the dial formed by a stack of four superimposed layers, each of said layers including one or more constituent element(s) of the device for determining a magnetic event, according to a first embodiment of the invention;

FIG. 3 shows a schematic view of this first variant of the dial provided with the device for determining a magnetic event, according to the first embodiment of the invention;

FIG. 4 shows an exploded view of a second variant of the dial formed by a stack of three superimposed layers, each of said layers including one or more constituent element(s) of the device for determining a magnetic event, according to a second embodiment of the invention, and

FIG. 5 shows a schematic view of this second variant of the dial provided with the device for determining a magnetic event, according to the second embodiment of the invention.

### DETAILED DESCRIPTION OF THE INVENTION

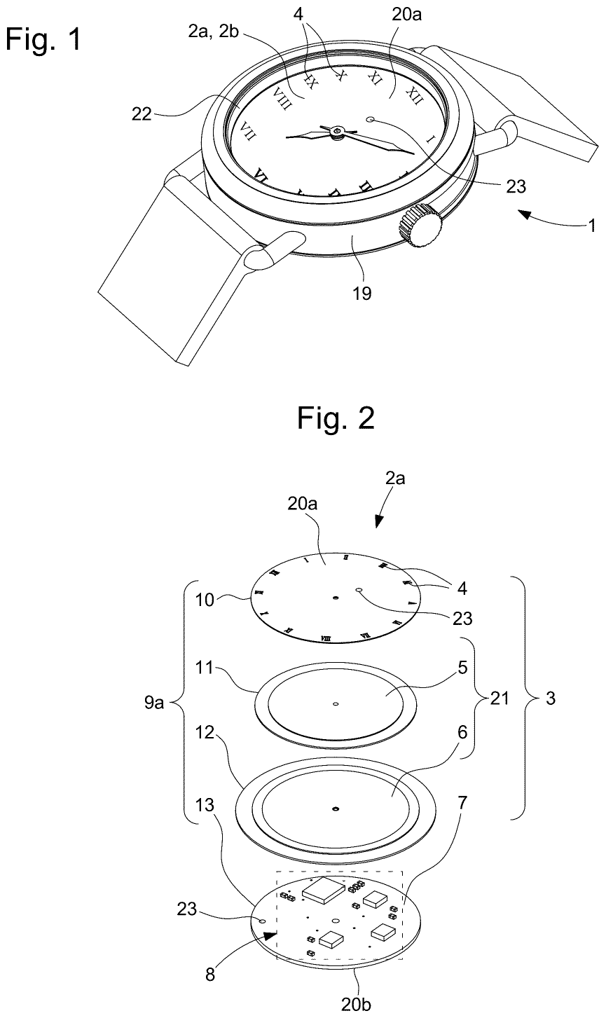

FIG. 1 shows a schematic illustration of a watch 1 comprising a case 19 with a middle to which a back and a crystal 22 are attached, a set of components forming a horological movement, and a dial 2a, 2b arranged between the horological movement and the crystal 22.

In a manner known to a person skilled in the art, the horological movement drives a set of hands comprising an hour hand, a minute hand and possibly a second hand. To this end, the dial 2a, 2b includes a through hole receiving the axis of the hands. This dial 2a, 2b also comprises two faces 20a, 20b including:
A so-called visible face 20a visible from the outside of the watch 1, also known as the “visible portion” or “visible upper portion” of this dial 2a, 2b, and
a so-called hidden face 20b arranged opposite the horological movement in an enclosure of the case 19 of the watch 1, this face 20b being otherwise so-called the “hidden portion” or “hidden lower portion” of this dial 2a, 2b.

Such a visible face 20a may comprise, in a non-limiting and non-exhaustive manner, at least one graphic representation such as:
a reference (or display) element like, for example, a digit, an index, a line or a dot contributing, with or without the hands, to the display of a horological information/measurement or a physical information/measurement measured by a sensor or the like comprised in the movement;
an inscription, a pattern, a text, a logo, etc.

These visible 20a and hidden 20b faces are substantially flat and/or parallel and/or opposite each other. In other variants, note that the dial 2a, 2b may comprise a domed visible face with a hidden face which may be domed or flat. These faces 20a, 20b are also joined together by a peripheral wall of this dial 2a, 2b.

Moreover, it should be noted that in the embodiments illustrated in FIGS. 1 to 5, the dial 2a, 2b preferably has a circular shape. It should be understood that the invention may also be implemented for dials 2a, 2b having other shapes like, for example, a triangular shape or a quadrilateral-like shape.

In the embodiments of the invention, the horological movement is a mechanical movement. Alternatively, this movement may be an electromechanical or electronic movement. Hereafter, we will refer to a mechanical watch when its movement is mechanical, an electronic when watch it includes an electronic movement and an electromechanical watch when it includes an electromechanical movement.

With reference to FIGS. 2 and 4, such a dial 2a, 2b comprises a standalone device for determining a magnetic event 3. This device for determining a magnetic event 3 comprises its own electric power supply means, as we shall see later on. Such a device for determining a magnetic event 3 is said to be standalone in particular with respect to the movement of the watch 1 and in particular with respect to the energy source of this movement, for example when this source is an electric power supply like in an electromechanical movement. Under these conditions, it should be understood that the energy used by this device for determining a magnetic event 3 is not done to the detriment of the autonomy of the movement.

In this context, the dial 2a, 2b can be removably mounted in the watch 1 regardless of the type of the watch 1. The only condition to be met is that the dial 2a, 2b comprises this device for determining a magnetic event 3, which is therefore standalone with respect to the movement of the watch 1. This dial 2a, 2b is also called a “standalone dial” because it is not connected, in particular electrically, to the movement of the watch 1. This dial 2a, 2b may be considered as a part attached to the watch 1.

This device for determining a magnetic event 3 comprised in this dial 2a, 2b, includes a module 4 for reporting the magnetic event, a standalone electric power supply unit 21, at least one magnetic sensor 23, and a control unit 7.

In this device 3, the reporting module comprises:
at least one element capable of generating a light signal 4, such as a light source 4 also known as a light source, enabling the device 3 to broadcast a visual message relating to the determined magnetic event;
at least one element capable of generating a vibratory signal, such as a piezoelectric vibrator, a vibrator comprising an ERM motor (standing for eccentric rotating mass vibration motor) or an LRA motor (standing for linear vibration motor), enabling the device 3 to broadcast a message in the form of vibrations relating to the determined magnetic event and/or
at least one element capable of generating an audible signal, such as a loudspeaker, enabling the device 3 to broadcast an audible message relating to the determined magnetic event.

As mentioned above, said at least one light source 4 is implemented in particular to help display a visual/luminous message relating to the determined magnetic event. Each light source 4 may correspond to any electroluminescent element selected from a non-exhaustive and non-limiting list comprising:
an electroluminescent capacitor known by the acronym LEC, standing for “Light-Emitting Capacitor”;
a light-emitting diode such as LED (acronym for “Light-Emitting Diode”), OLED (acronym for “Organic Light-Emitting Diode”), AMOLED (acronym for “Active-Matrix Organic Light-Emitting Diode”) or QLED (acronym for “Quantum Light-emitting diode”);
any electroluminescent material activated by a local electric field;
any electroluminescent material activated by an electric current;
any combination of these electroluminescent elements.

It should be noted that this light source 4 may, in some embodiments of the invention, be a light source 4 capable of forming an extended light source. This allows conferring a predetermined shape on the extended light source, typically, without this being exhaustive or limiting, a shape relating to a graphic representation of a digit, letter, logo or text. It should also be noted that this light source 4 can produce light in any colour and/or in any direction.

In this device for determining a magnetic event 3, said at least one magnetic sensor 23 is configured to detect a magnetic field present in the enclosure of the case 19 of the watch 1.

This magnetic sensor 23 is an electronic device designed to participate in the detection and measurement of at least one magnetic field. This magnetic field 23, to which the watch 1 may be exposed, may be generated by a permanent magnet, an electromagnet or an electric current. This sensor 23 comprises an element sensitive to magnetic fields, such as a Hall-effect transistor or a magnetic resistor, as well as an electronic circuit which converts the magnetic signal into a usable electrical output.

This sensor may be a REED magnetic sensor or reed switch, based on the MEMS technology, an acronym for “Micro-Electronic-Mechanical System”, and consists of a series of electrodes placed in a hermetically-sealed chip. When a magnetic field is detected, the contacts inside the REED switch close or open, generating an electrical signal.

This sensor may be a Hall-effect sensor allowing measuring a variation in magnetic field which is converted into an electrical signal. This sensor is so-called a Hall-effect sensor when internal electronics of the sensor enhance its performance by amplifying or processing the signal before transmission, thereby limiting the risk of environmental disturbances.

This sensor may be a magnetoresistance sensor using the variation in electrical resistance of a material in the presence of a magnetic field. When the magnetic field changes, the resistance of the material changes proportionally. This change in resistance is measured and converted into an electrical signal to determine the strength of the magnetic field.

Note that in another variant, this magnetic sensor 23 may be any combination of the following sensors: at least one REED magnetic sensor, at least one Hall-effect sensor and at least one magnetoresistance sensor.

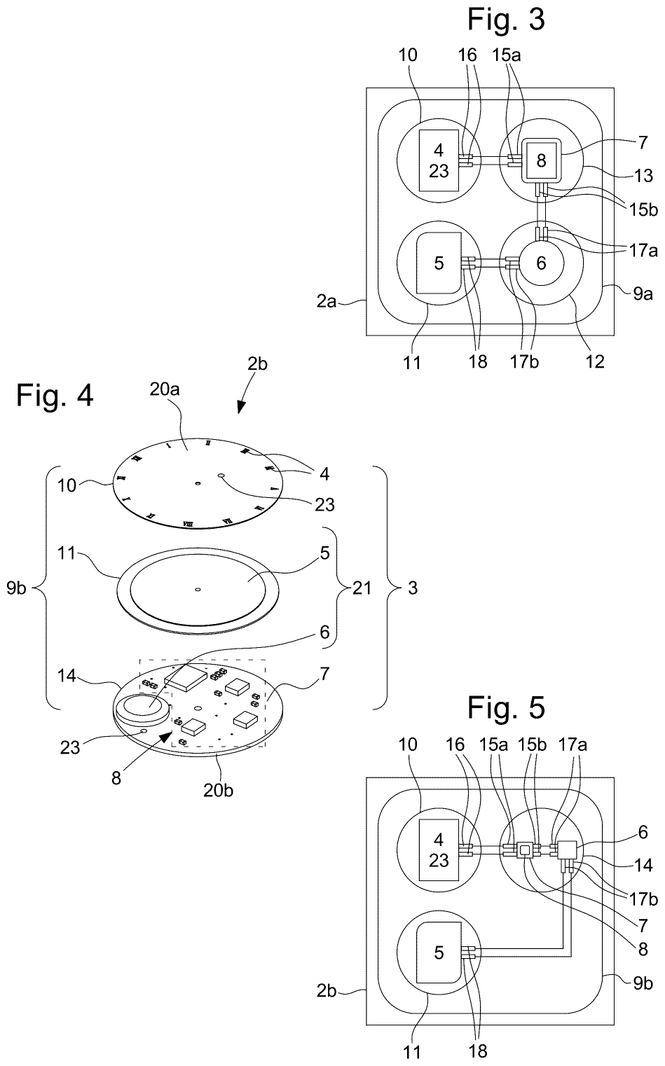

In this determination device 3, the standalone electric power supply unit 21 includes an electrical energy accumulator 6 and a photovoltaic module 5 comprising at least one photovoltaic cell, also known as a solar cell. This photovoltaic module 5 is connected to the electrical energy accumulator 6 via connection elements referenced 17b and 18 in FIGS. 3 and 5. This photovoltaic module 5 may comprise one or more elementary cell(s) of the heterojunction or multijunction type, connected in parallel or in series. Each photovoltaic cell of this module 5 can be made, in a manner known to a person skilled in the art, from semiconductor materials based on copper, indium, gallium and selenium, based on cadmium telluride, based on monocrystalline gallium arsenide or based on monocrystalline or polycrystalline silicon, or with perovskites. It should be noted that these examples are not limitative and that a person skilled in the art will be able to find the type of photovoltaic cell suitable for the invention.

In this device for determining a magnetic event 3, the control unit 7, also known as a microcontroller, includes an electronic circuit 8 comprising hardware resources, in particular at least one processor cooperating with memory elements as well as address, data and control buses. This control unit 7 is connected to said at least one light source 4, to said at least one magnetic sensor 23 and to the standalone electric power supply unit 21. Such a control unit 7 comprises in its memory elements 4 an algorithm for determining a magnetic event.

This algorithm may be the subject of automatic training, also known as machine learning, which is preferably supervised. To do so, the control unit 7 which participates in implementing such training, comprises training data from magnetic field measurements and training data from specific magnetic events relating to the watch 1. This training aims to improve the algorithm and in particular the resulting model in order to minimise the error between “estimation and reality” in the context of assessment of a given magnetic field present in the enclosure of the case 19 of the watch 1 as a function of a magnetic field measurement relating to this event.

It should be noted that such an algorithm which is executed by the processor of this control unit 7 may also take into account other types of events in order to improve the determination of the magnetic event, on the basis of data originating from event sensors comprised in this determination device 3. These events may include, but are not limited to: the detection of a particular level of luminosity in the environment of the watch 1, the detection of a particular visual object, the detection of a movement performed by a portion of the user's body comprising this watch 1, etc. In this context, the event sensor of this determination device 3, comprises in particular and in a non-limitative and non-exhaustive manner:
a luminosity sensor allowing detecting the ambient luminosity level;
a movement sensor for detecting a movement of a portion of the user's body comprising the watch 1, such as a gyroscopic and/or inertial sensor in the form of an electronic component of the gyroscopic and/or inertial electromechanical microsystem circuit type, and/or
an optical sensor of the photographic sensor type.

Moreover, when the determination device 3 comprises several light sources 4, the operation of these can then be managed/controlled by the control unit 7 simultaneously and/or in sequence. In addition, each light source 4 is managed/controlled by this control unit 7 separately. In this context, the management of the operation of each light source 4 may consist of, but is not limited to, the following operations: sequential switching on or off, simultaneous switching on or off of two or more light sources 4, flashing of one or more light source(s) 4, definition of a flashing frequency for each light source 4, a flashing duration for each light source 4, a switching on or off duration for each light source 4, etc.

Such a control unit 7 may also comprise in its memory elements an algorithm for managing the electrical energy accumulator 6, in particular the management of recharging thereof by the photovoltaic module 5 and the management of the electrical consumption by said light source 4 and also of said at least one magnetic sensor 23.

As mentioned above, the standalone device for determining a magnetic event 3 is therefore comprised in the dial 2a, 2b. In this configuration, the constituent elements of this device for determining a magnetic event 3, namely the reporting module 4, the electrical energy accumulator 6, the photovoltaic module 5 and said at least one magnetic sensor 23 and the control unit 7, are comprised in one or more layers 10, 11, 12, 13, 14 forming this dial 2a, 2b.

With reference to FIGS. 2 to 5, this dial 2a, 2b is formed by or consist of a stack 9a, 9b of a plurality of thin/fine layers 10, 11, 12, 13, 14, these layers 10, 11, 12, 13, 14 are joined together by a joining element such as an adhesive substance so as to unify them in order to obtain a stack 9a, 9b of monolithic thin layers thus forming a one-piece dial 2a, 2b. This joining element may also be a clip or a screw. Such layers 10, 11, 12, 13, 14 are superimposed in the stack 9a, 9b of layers, i.e. they are arranged on top of one another in this dial 2a, 2b in a defined order. Note that such a stack 9a, 9b of layers may also be called an assembly of layers. In this stack 9a, 9b, the layers are substantially similar, having upper and lower surfaces of substantially the same areas/surfaces, thus helping form the peripheral wall of the dial 2a, 2b, which has no relief.

It should be noted that these thin or fine layers are layers that each has a micrometric thickness. Indeed, each layer may have a thickness comprised between 1 and 100 μm, preferably 2 μm, or preferably 3 μm. With regards to the thickness of the dial 2a, 2b, it may be between 8 and 400 μm, preferably 6 μm or preferably 12 μm or preferably 100 μm or preferably 200 μm or preferably 300 μm.

Thus, such a one-piece dial 2a, 2b has the additional advantage of being removably mounted in the case 19 of the watch 1, as well as facilitating integration thereof into this case 19.

In a first variant of this stack 9a of layers illustrated in FIG. 3, the latter consists of four successive thin layers 10, 11, 12, 13 as follows:
a first layer 10 forming/making up the visible face 20a of the dial 2a including said at least one magnetic sensor 23 and/or said at least one light source 4 3;
a second layer 11 including the photovoltaic module 5;
a third layer 12 including an electrical energy accumulator 6, also known as a rechargeable battery, and
a fourth layer 13 forming the hidden face 20b of the dial 2a including said at least one magnetic sensor 23 and/or the control unit 7.

The first layer 10 of this stack 9a is preferably rigid or semi-rigid compared with the second, third and fourth thin/fine layers 11, 12, 13 which are preferably soft or flexible. It should be understood herein that such a first layer 10 helps structurally stiffen the stack 9a of thin layers and therefore the dial 2a.

In this stack 9a, each of the first, second, third and fourth layers 10, 11, 12 and 13 comprises an upper surface and a lower surface.

As regards the first layer 10, it is formed by a transparent or translucent or at least partially transparent or at least partially translucent rigid or semi-rigid substrate. Such a substrate is made of a material having a transmittance to solar radiations, in particular ultraviolet radiations, also known as UVT (standing for “Ultra-Violet Transmission”) which is comprised between 65 and 95 percent. This transmittance is preferably 85 percent. Such a material may be transparent or translucent. This material may be, but is not limited to, a polymer, glass or ceramic.

In this context, it should be understood that this substrate is configured so that:
the light produced by said at least one light source could escape to the outside of the dial 2a, 2b and therefore of the watch 1, and
the light originating from the environment of the watch 1 could penetrate the dial 2a, 2b in the direction of the photovoltaic module 5 of the device for determining a magnetic event 3, this light comprising solar radiations when it is of natural origin.

In other words, this transparent or translucent substrate is configured so that light, in particular solar radiation, can pass through it and power the photovoltaic module 5 so that the latter could convert the solar energy originating from this radiation into electrical energy.

This first layer 10 also comprises at least one light source 4 which is arranged in the body of the substrate. Such an arrangement of the light source 4 in this substrate is configured to ensure illumination of all or part of the visible face 20a of the dial 2a. For example, illumination of a graphic representation such as a reference element (or display) like a number, an index, a line, a dot or illumination of one or more hands, or illumination of all or part of the surface of the visible face of the dial 2a. In one variant, this light source 4 may have a predetermined shape such as the shape of a number, a letter, an index, a line, a dot, a logo or a text.

This lighting may be backlighting or semi-direct lighting when the light source 4 is arranged in a cavity defined in the substrate. More specifically, this cavity may be a blind opening made in the lower surface of this substrate. In this configuration, when the bottom of this cavity comprises a graphic representation, the luminous radiation, or the light, produced by this light source 4 can escape towards the outside of the dial 2a via the visible face 20a of this dial 2a, thus allowing viewing at least one graphic representation in the dark. In particular, the light radiation escaping from the visible face 20a draws the outline of this graphic representation. In this context, this graphic representation comprised in or on the upper surface or on the lower surface of the substrate forming the first layer 10, is preferably opaque or non-translucent or non-transparent.

This lighting may be direct lighting when the light source 4 is arranged in a cavity defined in the substrate. This cavity may be a blind opening made in the lower surface of this substrate, the bottom of which is devoid of any graphic representation. In this configuration, the luminous radiation, or light, produced by this light source 4 can escape through the bottom of this cavity towards the outside of the dial 2a and therefore through the visible face 20a of this dial 2a.

This lighting may also be direct illumination when the light source 4 is arranged in a through opening extending through the thickness of the substrate of the first layer 10, opening out at its two ends respectively in the upper and lower surfaces of this substrate. In this configuration, all or part of the light source 4 may project from the upper surface of this substrate and therefore from the first layer 10 or from the visible face 20a of the dial 2a to form a graphic representation such as an index, a number, a dot, a line, etc.

Such lighting may also be remote lighting when said at least one light source 4 is coupled to at least one waveguide. This waveguide, also known as a light guide, allows carrying the light from the point where it is injected into the guide up to the substrate or up to an area of the substrate (e.g. cavity, through opening) close to the upper surface of this substrate. Such a light guide may be an optical fibre which allows circumventing any obstacles that might arise in the substrate, for example between the electroluminescent element and the area of the substrate close to the upper surface of this substrate, through which the light will escape. In this variant, it is therefore the light that is brought, via the waveguide, from the electroluminescent element up to this area of the substrate to be illuminated.

In such a configuration, a first end of the waveguide is coupled to the light source 4 and a second end of the waveguide may be arranged in:
a cavity which may be a blind opening made in the lower surface of the substrate of this first layer 10, or
a through opening extending through the thickness of the substrate of the first layer 10 and opening at its two ends respectively into the upper and lower surfaces of this substrate and therefore of the first layer 10. Thus, this second end can project from the upper surface of the substrate or of this first layer 10 or from the visible face 20a of the dial 2a in order, for example, to form a graphic representation of this dial 2a like, for example, a reference element such as an index, a number, a point, a line, etc.

In this context, indirect lighting may be achieved by one single light source 4 comprised on the lower surface of the substrate of this first layer 10 and coupled to several waveguides, the second ends of which are arranged in:
cavities each emitting light radiation, originating from this light source 4, this radiation escaping to the outside of the dial 2a via the visible face 20a, thus enabling at least one graphic representation to be viewed in the dark. In this context, this graphic representation comprised in or on the visible face 20a of the dial 2a, or the upper surface of the substrate, is preferably opaque, and/or
through apertures projecting, or not, from the upper surface of this substrate in order to form marker elements such as an index, a line or a dot, and each emitting a light radiation originating from this light source 4.

In this first layer 10, the light source 4 is applied/fastened to the lower surface of the substrate of this first layer 10, in a cavity or on an inner wall of a previously mentioned through opening, by printing or evaporation.

In this first layer 10, the magnetic sensor 23 is arranged in/on this substrate in order to be able to measure magnetic fields present in the enclosure of the watch 1 case 19. This magnetic sensor 23 may be arranged on or under the upper surface of this substrate forming the first layer 10. When arranged in the substrate, this magnetic sensor 23 is positioned in a blind cavity formed in this upper surface. In one variant, it may be arranged in a blind cavity made in the lower surface of this substrate having this upper surface as its bottom. In this configuration, the magnetic fields passing through the dial 2a, 2b and therefore the visible face 20a may be measured by said magnetic sensor 23. This substrate may also comprise a through hole connecting the upper and lower surfaces together and in which the magnetic sensor 23 may be arranged.

Furthermore, it should be noted that the lower surface of this first layer 10 may be self-adhesive in order to contribute in assembly thereof with the second layer 11.

In this stack 9a, the second layer 11 comprises a substrate including the photovoltaic module 5. Such a substrate is preferably flexible or soft. The substrate of the second layer 11 may be a film on which the photovoltaic module 5 is arranged. Finally, this substrate may be made of a material belonging to the polymer family.

In this second layer 11, the photovoltaic module 5 preferably extends over the entirety of a so-called active area of the upper surface of this substrate. This active area is a portion of the upper surface of the substrate that is able to receive light originating from the lower surface of the first layer 10 of the dial 2a. This light, which has passed through all or part of the first layer 10, originates from the external environment of the dial 2a, and therefore of the watch 1, in this case mainly from solar radiation when it is of natural origin.

It should be noted that the photovoltaic module 5 is applied to the upper surface of this substrate using inkjet or screen-printing processes or using thermal evaporation printing processes. We will refer herein to a second layer 11 comprising a printed photovoltaic module 5. In particular, a photovoltaic module 5 printed on the substrate of the second layer 11.

It should be noted that once the photovoltaic module 5 has been applied to the substrate, a layer of a self-adhesive substance may be deposited over all or part of the upper surface and/or the lower surface of the substrate. Under these conditions, the second layer 11 may be a self-adhesive layer which helps facilitate assembly thereof with the other layers, in particular with the first layer 10 and/or the third layer 12 of this stack 9a.

In the stack 9a, this third layer 12 also comprises a preferably flexible or soft substrate, including the electrical energy accumulator 6 of the standalone determination device 3. This substrate of the third layer 12 may be a film on which the accumulator 6 is comprised. Such a substrate may be made of a material belonging to the polymer family.

This accumulator 6 may be a lithium battery or a semiconductor battery. Such a battery 6 is applied to the upper surface of this substrate using processes known in the state of the art, such as:
printing processes on a flexible polymer substrate, for example in the case of a lithium battery, or
three-dimensional printing processes, for example for a semiconductor battery such as a lithium-metal semiconductor battery.

We will refer herein to a third layer 12 comprising a printed electrical energy accumulator 6. In particular, an electrical energy accumulator 6 printed on the substrate of the third layer 12.

Thus, such processes allow obtaining a third layer 12 comprising this accumulator 6 which is soft and ultra-thin.

Furthermore, it should be noted that once the accumulator 6 has been applied to the substrate, a layer of a self-adhesive substance can be deposited over all or part of the upper surface and/or the lower surface of this substrate. Under these conditions, the third layer 12 can be a self-adhesive layer which helps facilitating assembly thereof with the other layers, in particular with the second layer 11 and/or the fourth layer 13 of this stack 9a.

Note that this accumulator 6 is used to store the electrical energy produced by the photovoltaic module 5 and to release it on demand to power the determination device 3, said at least one light source 4 and said at least one magnetic sensor 23.

In this stack 9a, this fourth and final layer 13 forms the hidden face of the dial 2a. Such a fourth layer 13 is formed by a preferably flexible or soft substrate including the control unit 7. Such a substrate of the fourth layer 13 may be, for example, a flexible PCB on which this control unit 7 is arranged, in particular on the upper surface of this PCB and therefore of the substrate. In this context, the construction of the control unit 7 on this upper surface of the substrate may be carried out using three-dimensional printing processes or polymer printing processes.

In this last and fourth layer 13, the magnetic sensor 23 is arranged in/on this substrate in order to be able to receive magnetic fields present in the enclosure of the watch 1 case 19. This magnetic sensor 23 can be arranged on or under the lower surface of this substrate forming the fourth layer 13. When arranged in the substrate, this magnetic sensor 23 is positioned in a blind cavity formed in this lower surface. In one variant, it can be arranged in a blind cavity made in the upper surface of this substrate having this lower surface as its base. In this configuration, the magnetic fields passing through the dial 2a, 2b and therefore the hidden face 20b can be measured by said magnetic sensor 23. This substrate can also comprise a through hole connecting the upper and lower surfaces together and in which the magnetic sensor 23 can be arranged.

In the second variant, the stack 9b forming the dial 2b comprises three thin layers 10, 11, 14, joined together. Note that this second variant differs from the first variant in that it comprises three layers 10, 11, 14 instead of four layers 10, 11, 12, 13, like in the first variant. In this second variant, the electrical energy accumulator 6 of the determination device 3 is now comprised in the third and last layer 14 of this stack 9b with the control unit 7.

Such a third and final layer 14 of this stack 9b, forming the hidden face of the dial 2b, consists of a preferably flexible or soft substrate, on which are built, preferably on the upper surface of this substrate, the battery 6 and the electronic circuit 8 making up the control unit 7. Such a construction of the battery 6 and the control unit 7 on this upper surface of the substrate may be carried out using three-dimensional printing processes or polymer printing processes. It should be noted that such a substrate can be, for example, a flexible PCB.

In this last and third layer 14 of this second variant, the magnetic sensor 23 is arranged in/on this substrate so as to be able to receive magnetic fields present in the enclosure of the watch 1 case 19. This magnetic sensor 23 can be arranged on or under the lower surface of this substrate forming the third layer 14. When arranged in the substrate, this magnetic sensor 23 is positioned in a blind cavity formed in this lower surface. In one variant, it can be arranged in a blind cavity made in the upper surface of this substrate having this lower surface as its base. In this configuration, the magnetic fields passing through the dial 2a, 2b and therefore the hidden face 20b can be measured by said magnetic sensor 23. This substrate can also comprise a through hole connecting the upper and lower surfaces together and in which the magnetic sensor 23 can be arranged.

In summary, in this second variant, the stack 9b then comprises:
a first layer 10 forming the visible face 20a of the dial 2b including said at least one magnetic sensor 23 and/or said at least one light source 4;
a second layer 11 including the photovoltaic module 5, and
the third layer 14 forming the hidden face 20b of the dial 2b including said at least one magnetic sensor 23 and/or the accumulator 6 and the control unit 7.

Note that in this second variant, the first and second layers 10, 11 are similar to those of the first variant of the stack 9a.

Moreover, with reference to FIGS. 3 and 5, the electronic circuit 8 of the control unit 7 comprises first connection elements 15a which are connected to connection elements 16 of:
said at least one light source 4 for managing the operation of this light source 4, in particular for displaying a message relating to the determined magnetic event, and
said at least one magnetic sensor 23 to help determine the magnetic event.

This electronic circuit 8 also comprises second connection elements 15b connected to first connection elements 17a of the accumulator 6.

Furthermore, it should be noted that the event sensors of the determination device 3, mentioned before, are preferably arranged in the first layer 10 and/or the last layer 13, 14 of the stack 9a, 9b of layers while being connected to the control unit 7 of this device 3.

In a third variant not shown, the stack of thin/fine layers forming the dial comprises two interconnected layers. Note that this third variant differs from the second variant in that it therefore comprises two layers instead of three layers 10, 11, 14, like in the second variant. In this third variant, the photovoltaic module 5 of the standalone determination device 3 is now included in the first layer and in particular on the lower surface of the substrate forming this first layer. This photovoltaic module 5 can be applied to this lower surface of the substrate of this first layer using inkjet printing or screen-printing processes or using thermal evaporation printing processes. It should therefore be noted that this first layer is then similar to the first layers 11 of the first and second variants, with the exception that in this third variant, the first layer additionally comprises the photovoltaic module.

Moreover, in the third variant, and similarly to the second variant, the electrical energy accumulator 6 of the standalone determination device 3 is included in the second and last layer of this stack with the control unit 7. Such a second layer, forming the hidden face of the dial, consists of a preferably flexible or soft substrate, on which are built, preferably on the upper surface of this substrate, the accumulator 6 and the electronic circuit 8 making up the control unit 7. This construction of the battery 6 and of the control unit 7 on the upper surface of the substrate can be carried out using three-dimensional printing processes or polymer printing processes. It should be noted that such a substrate can be a flexible PCB, for example.

In summary, in this third variant, the stack of layers then comprises:
a first layer forming the visible face 20a of the dial including said at least one magnetic sensor 23 and/or said at least one light source 4 and the photovoltaic module 5, and,
a second layer forming the hidden face 20b of the dial including said at least one magnetic sensor 23 and/or the accumulator 6 and the control unit 7.

Thus, in this dial 2a, 2b, the determination device 3 comprises the magnetic sensor 23 which converts a received magnetic field into an electrical signal which is transmitted to the control unit 7. In this context, when at least one magnetic field is detected in the enclosure of the watch case 19, an electrical signal comprising data relating to one or more magnetic field(s) is then transmitted by the magnetic sensor 23 to the control unit 7. This control unit 7 then processes these data on the basis of the algorithm for determining a magnetic event. Such a processing allows identifying the magnetic field as a function, in particular, of the characteristics of at least one magnetic field picked up by the magnetic sensor, namely, in particular, the magnetic induction field and the magnetic excitation field of said at least one magnetic field.

Such a determination of a magnetic event may enable this dial 2a, 2b to implement various functions of this watch. For example, a function of this watch may correspond to the detection of a magnetic field present in the environment of the watch 1 which is likely to result in a loss of timekeeping accuracy. Indeed, it might happen that the operation of the mechanism is disturbed by a magnetic field present in the environment of the watch 1. As a result, although the watch's internal clock provides an accurate indication of the current time, the hour and minute hands provide a distorted indication of this current time, because the trains have been stopped under the effect of this magnetic field. It is therefore necessary to resynchronise the position of the hour and minute hands. Therefore, as part of this function, the control unit 7 can generate a visual, vibrating and/or audible message depending on this event, which reports this loss of accuracy by controlling/driving the reporting module 4.

Advantageously, such a dial 2a, 2b provided with this device 3 allows, for example, solving a problem of accuracy in a mechanical watch which has not been demagnetised after being exposed to a magnetic field which has generated residual magnetisation of the internal components of the watch 1. In this context, if the values detected by the device 3 exceed a threshold, the reporting module 4 generates an audible, visual and/or vibrating message relating to this specific magnetic event. Such a message allows warning the wearer to take the watch to the after-sales service to have it demagnetised.

It should be understood in this context that various thresholds can be defined as a function of at least one characteristic of the magnetic field and which would reveal different levels of seriousness, particularly in the context of the operation of the movement. Under these conditions, various implementations of at least one light source 4 of the reporting module may result. Thus, a first implementation may report that a demagnetisation of the watch is recommended, while a second implementation may report that a demagnetisation is necessary.

It should be noted that threshold detection can also be used as a preventive measure. If the magnetic sensor records a rapidly increasing magnetic field, the implementation of at least one light source can warn the wearer that he/she is approaching his/her watch to a “magnetic” risk area. This could, for example, prevent the wearer from placing his/her watch near a smartphone with magnets that could magnetise the watch.

It goes without saying that the present invention is not limited to the embodiments just described and that various simple modifications and variants may be considered by a person skilled in the art without departing from the scope of the invention as defined by the appended claims.

1. A dial for a watch comprising a standalone device for determining a magnetic event, such a dial comprises a visible face and a hidden face, said dial being formed by a stack of thin layers of material extending between these two faces, each of said layers comprising one or more of the functional elements included in said device:
at least one magnetic sensor,
a magnetic event reporting module,
a standalone electric power supply unit, and
a control unit for managing the operation of said reporting module and said at least one magnetic sensor.

2. The dial according to claim 1, wherein said at least one magnetic sensor comprises a REED magnetic sensor, a Hall-effect sensor and/or a magnetoresistance sensor.

3. The dial according to claim 1, wherein the magnetic event reporting module comprises:
at least one element capable of generating a light signal;
at least one element capable of generating a vibration signal, and/or
at least one element capable of generating an audible signal.

4. The dial according to claim 1, wherein the stack of thin layers of material comprises a first layer provided with the visible face of the dial and comprising said at least one magnetic sensor and said reporting module.

5. The dial according to claim 1, wherein said at least one magnetic sensor is arranged in a cavity formed in the hidden face of this dial.

6. The dial according to claim 1, wherein said first layer is configured to be crossed in whole or in part by light radiation, in particular solar radiation.

7. The dial according to claim 1, wherein said first layer is wholly or partly transparent or translucent.

8. The dial according to claim 1, wherein the stack of thin layers of material includes a second layer comprising a photovoltaic module making up the standalone electric power supply unit.

9. The dial according to claim 1, wherein the stack of thin layers of material includes a second layer comprising a photovoltaic module making up the standalone electric power supply unit, the second layer comprising a substrate on which the photovoltaic module is printed.

10. The dial according to claim 1, wherein the stack of thin layers of material includes a second layer comprising a photovoltaic module making up the standalone electric power supply unit, said photovoltaic module being arranged on an active area of said second layer, said area being configured to receive light radiations originating from the first layer of the stack of thin layers of material.

11. The dial according to claim 1, wherein the stack includes a third layer comprising an electrical energy accumulator making up the standalone electric power supply unit.

12. The dial according to claim 1, wherein the stack includes a third layer comprising an electrical energy accumulator making up the standalone electric power supply unit, the third layer comprising a substrate on which the electrical energy accumulator is printed.

13. The dial according to claim 1, wherein the stack includes a fourth layer forming a hidden face of the dial comprising the control unit.

14. The dial according to claim 1, wherein the stack includes a third layer comprising a hidden face of the dial including the control unit and an electrical energy accumulator making up the standalone electric power supply unit.

15. The dial according to claim 1, wherein the first layer is rigid compared to the other layers comprised in the stack of thin layers of material which are soft.

16. The dial according to claim 1, wherein said visible and hidden faces are flat or domed.

17. A watch comprising the dial according claim 1.

18. The watch according to claim 17, comprising a mechanical, electronic or electromechanical horological movement.
